(19) United States
(12) Patent Application Publication
(10) Pub. No.: US 2006/0138443 A1
(43) Pub. Date: Jun. 29, 2006

(54) Encapsulation and packaging of ultraviolet and deep-ultraviolet light emitting diodes

(75) Inventors: Zhaoyang Fan, Manhattan, KS (US); Hongxing Jiang, Manhattan, KS (US); Jingyu Lin, Manhattan, KS (US)

Correspondence Address: SHOOK, HARDY & BACON LLP;INTELLECTUAL PROPERTY DEPARTMENT, 2555 GRAND BLVD, KANSAS CITY,, MO, 64108-2613, US

(73) Assignee: III-N Technology, Inc.

(21) Appl. No.: 11/020,762

(22) Filed: Dec. 23, 2004

(51) Int. Cl. H01L 33/00; H01L 29/24

(52) U.S. Cl. 257/100

(57) ABSTRACT

Disclosed are the materials and methods used to package and encapsulate UV and DUV LEDs. These LEDs have emission wavelengths in the range from around 360 nm to around 200 nm. The UV/DUV LED die or its flip-chip bonded subassembly are disposed in a low thermal resistance packaging house. Either the whole package or just the UV/DUV LED is globed with a UV/DUV transparent dome-shape encapsulation. This protects the device, enhances light extraction, and focuses the light emitted. The dome-shape encapsulation may be comprised of optically transparent PMMA, fluorinated polymers or other organic materials. Alternatively it might be configured having a lens made from sapphire, fused silica or other transparent materials. The lens material is cemented on the UV/DUV LED with UV/DUV transparent polymers.

### BACKGROUND OF THE INVENTION

1. Field of the Invention

The present invention relates to the encapsulation and packaging of ultraviolet (UV) and deep-ultraviolet (DUV) light emitting diodes (LEDs) semiconductor devices, especially those with emitting wavelengths between around 360 nm and 200 nm.

2. Description of the Prior Art

The advances in III-nitride semiconductors (including GaN, InN, AlN, and their alloys), especially those used in high Al-content AlGaN and AlInGaN based light emitting diode (LED) technologies, allow for the first time to push the emitting wavelength of the semiconductor LED to the UV and DUV range. These new semiconductors, depending on Al content, have a bandgap up to 6.2 eV, which corresponds to an emitting wavelength down to 200 nm, covering the near-UV, UV, and DUV range.

The conventional LEDs based on GaAs, InP, or even InGaN, emit a wavelength in the visible to near infrared (IR) range. For these visible or near-IR LEDs, an industry-standard package is shown in FIG. 1. Referring to the figure, it may be seen that an LED with a small LED chip 12 mounted on a metal frame 14, which is then encapsulated in an optical transparent hemisphere epoxy dome lens 16. The hemisphere encapsulation is formed by molding and thermal or UV curing. The package provides the mechanical support via frame 14. Frame 14 also participates in the electrical interfacing of LED 12. Thus, it includes a cathode portion 18 and an anode portion 20. Portion 18 is electrically integrated with a cathode lead 22. Anode portion 20 is electrically integrated with an anode lead 24. Leads 22 and 24 are used to receive voltage from some outside source (not shown). This voltage is delivered to the LED by linking the upper surface (on the p-type semiconductor side) with the anode portion 20 using a wire bond 26. The n-type semiconductor side of the LED is soldered or otherwise secured to the cathode portion 18 of the frame.

Thermal dissipation with this device occurs through metal frame 14. The LED also normally includes an optically active reflector cup 28. Cup 28 serves to group the light generated by LED 12 and direct it into the focusing dome 16.

The encapsulation of the LED isolates the device from the ambient environment. This protects it from mechanical damage and environmental influence. More importantly, the LED package enhances the light extraction and focusing through the hemisphere transparent dome which has a high refractive index.

The FIG. 1—type arrangement, however, does not work with some newly-developed LEDs. One of the serious problems related with high-efficiency LEDs is the occurrence of generated light trapped in the high refractive index semiconductor itself without emitting out. This is caused by the total internal reflection. See E. Fred Schubert, Light-Emitting Diodes, pp89-92. Cambridge University Press, 2003. Semiconductors have large refractive indices (e.g., 2.5 for GaN; 3.4 for GaAs). Consequently, the light extraction angle (or the critical angle for light to escape) is only ˜23° for GaN and ˜17° for GaAs. Correspondingly, only about 4.2% (2.2%) of the light is extracted from each surface into air in a typical planar geometry GaN (GaAs) LED. The epoxy encapsulation with a typical index of 1.5 reduces the refractive index contrast between semiconductor and air. The lower index contrast at the semiconductor and epoxy interface increases the total-reflection angle. This enhances the light extraction efficiency. Futher, the encapsulation has a hemisphere shape. The shape is configured such that the light incident angle at the epoxy-air interface is always nearly perpendicular to the encapsulation surface. This prevents total internal reflection at the epoxy-air interface. Where the encapsulation is done with an epoxy having a refractive index of 1.5-1.6, the LED's efficiency typically increases by a factor of 2-4.

With the development of blue and near-UV LEDs and power white LEDs in recent years, however, the traditional epoxy-resin encapsulation has not worked so well. It has been discovered that—when using these new LED types—thermal aging and high-energy (short wavelength) photon absorption cause a yellowish phenomenon to occur in the traditional epoxy resin encapsulation. This dramatically degrades transparency, thus inhibiting light transmission.

Because of these problems, more stable silicone-resin and other epoxy-resin encapsulations have been introduced for blue, near UV and power-white LEDs. But these alternatives are limited in that they are transmission-inhibited with respect to light wavelengths below 400 nm and have cut-off wavelengths well above 300 nm (depending on composition). Further, the absorption of short-wavelength (λ<360 nm) UV and DUV light will dramatically degrade their performance.

With respect to UV and DUV LEDs, there are currently no acceptable options with respect to encapsulation and packaging. This greatly limits their usefulness. Because the conventional UV and DUV LEDs are unencapsulated, they emit from their planar surfaces. Thus, the angular spread of illumination coming from them is very broad. This makes them unusable for any application which requires focused light. It also makes the LED and its surrounding hardware vulnerable to damage and degradation.

In addition to the unencapsulated nature of conventional UV/DUV LEDs, the devices also have heat-management problems. For AlGaN or AlInGaN based UV/DUV LED devices, high Al-content degrades the semiconductor materials quality by introducing more dislocations and defects, and the UV/DUV LED light efficiency is low. To achieve a high optical power output the LED is typically run under a high current. This generates a significant amount of heat, and thus, thermal dissipation is a critical requirement for the packaging. The typical wire bonding and standard lead-frame package is not suitable for the thermal dissipation of UV/DUV LED devices.

Another deficiency in the prior art devices relates to the light absorption by UV/DUV LED structure itself. AlGaN or AlInGaN UV/DUV LEDs typically have a p-type layer on the top. This p-type layer has a low bandgap energy and will absorb the UV/DUV light. The n- and p-contact metals will also absorb light. These light-absorption problems render the common die bonding arrangement—where the LED chip is disposed in a packaging house in such a way that light is extracted from the top of the device—obsolete.

Because of these limitations of the prior art devices, there is a need in the art for a UV/DUV encapsulation and packaging technique which avoids the above-stated pitfalls.

### BRIEF SUMMARY OF THE INVENTION

The present invention provides materials and methods for the encapsulation and packaging of UV and DUV LEDs. The materials used to fabricate these UV and DUV LEDs are III-nitride semiconductors or other wide bandgap materials, which cover a wavelength range from around 360 nm down to 200 nm. The LED die may be directly bonded in a standard or customized package house and light is extracted from the semiconductor epilayer side, the so called direct die bonding. In another preferable method, the LED die with a typical transparent substrate (e.g., sapphire substrate) is flip-chip bonded on a thermal-conductive submount, and then mounted in a standard or customized package house with the light being extracted from the UV/DUV transparent substrate side. On the submount, one LED die, one LED-array die, or LED die arrays can be mounted. The submount provides electrical connections and wire bonding pads to connect the device to electrical leads of the packaging house.

In either methods, the device is encapsulated with hemispheres, ellipsoidal or other lens shapes made of sapphire, silica, PMMA (Polymethyl Methacrylate), different transparent fluoropolymers (e.g. Teflon™ AF, and Cytop™), or other UV/DUV transparent inorganic or organic materials to enhance the light extraction, and/or focus the UV/DUV light in the forward direction, and/or distribute the light uniformly. The encapsulation is constructed using a UV/DUV transparent lens which is cemented on using a UV/DUV transparent polymer or is directly molded thereon using special polymer resins such as PMMA, Teflon™ AF, or Cytop™.

These novel encapsulation and packaging arrangements will have utility in numerous technological areas. For example, the encapsulated, compact UV or DUV (UV/DUV) LEDs will be used for biological applications. Protein fluorescence is generally excited by UV light. Monitoring changes of intrinsic fluorescence in a protein can provide important information on its structural changes.

These new LEDs will also be medically useful. The compact nature of the UV or DUV LED light sources makes them ideal for medical research and surgical procedures. Some foreseen examples include the miniaturization of optical spectroscopy systems. The encapsulated LED embodiments of the present invention will be ideal for the non-invasive detection of precancerous cells in optically accessible organs and home-dialysis machines.

Compact encapsulated UV and DUV light sources will also have applications in fluorescence detection of chemical and biological agents, water and air purification, equipment/personnel decontamination, and fluorescence analysis of chemical and biological species. These applications all require a relatively intense and focused light beam (e.g., for direction into optical fibers)—an impossibility with the unencapsulated prior art UV/DUV LEDs.

### BRIEF DESCRIPTION OF THE SEVERAL VIEWS OF THE DRAWINGS

FIG. 1 is the cross sectional view of the standard LED indicator lamp package.

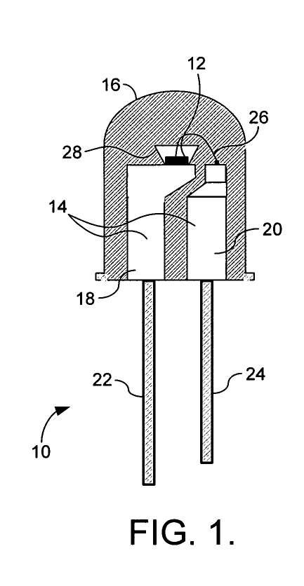

FIG. 2 is the cross sectional view of the flip-chip bonded UV/DUV LED structure with cemented hemisphere encapsulation that is transparent in the UV/DUV spectral region.

FIG. 3 compares the angular light intensity distribution from a DUV LED with and without the DUV hemisphere encapsulation described in FIG. 2.

FIG. 4 is the cross sectional view of a flip-chip bonded UV/DUV LED mounted in a custom package with hemisphere encapsulation molded from UV/DUV transparent polymers.

FIG. 5 is the cross sectional view of a flip-chip bonded UV/DUV LED sealed in a standard TO-header with encapsulated lens.

FIG. 6 is the cross sectional view of UV/DUV LED (without flip-chip bonding) directly mounted in a custom package with hemisphere encapsulation molded from UV/DUV transparent polymers.

### DETAILED DESCRIPTION OF THE INVENTION

In this invention, sapphire and fused silica lens, and UV/DUV transparent PMMA and fluoropolymers (e.g. Teflon™ AF, and Cytop™), are the preferred selections for the UV/DUV LED encapsulation. Since sapphire is the commonly used substrate for UV/DUV LEDs, it has been discovered that a sapphire lens is a good choice for the flip-chip bonded UV and DUV LED encapsulation. Sapphire is transparent down to 190 nm. Synthetic UV-grade fused silica has excellent transparency down to 170 nm and has minimal absorption characteristics. PMMA is a thermoplastic acrylic resin formed by the polymerization of methyl methacrylate. Because it has (i) a refractive index of around 1.5, (ii) excellent clarity down to about 250 nm, (iii) good abrasion resistance, and (iv) low moisture absorption it has proven suitable for UV and DUV LED encapsulation.

Two classes of polymers—fluorinated polymers (fluoropolymers) and siloxanes—exhibit very good transparency down to below 200 nm. Fluoropolymers, including: (i) side-chain-fluorinated polymers based on alicyclic and aromatic structures, (ii) main-chain-fluorinated base resins containing tetrafluoroethylene (TFE), and (iii) monocyclic fluorocarbons have been discovered to be acceptable for potential applications as 157-nm photoresist materials because of their outstanding optical clarity and transmission. Teflon™ AF from Dupont and Cytop™ from Asahi Glass Co. are two examples of fluoropolymers with high optical clarity at UV and DUV wavelengths.

The encapsulation material may also be other UV/DUV transparent inorganic materials such as calcium fluoride and magnesium fluoride or other organic materials such as polystyrene (PS) which exhibit transparency in the UV/DUV range.

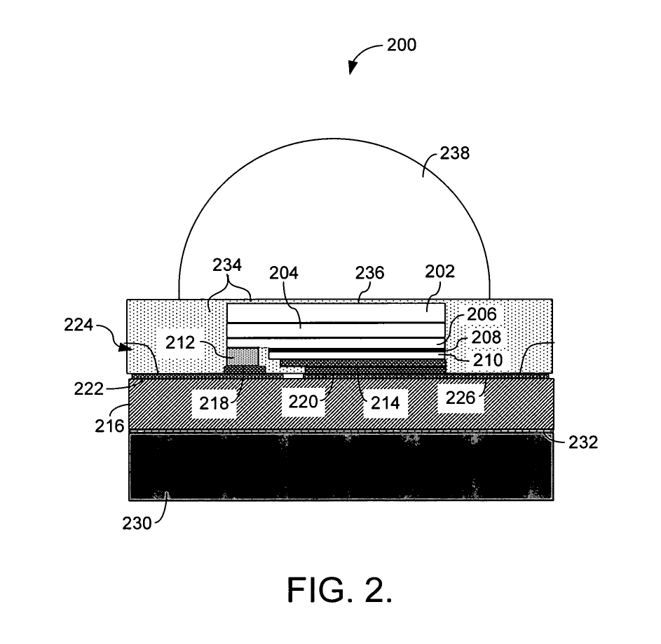

FIG. 2 illustrates the first embodiment of the invention. Disclosed in the figure is an AlGaN (or AlInGaN) based UV/DUV LED structure 200. LED 200 includes a substrate 202, an AIN epilayer 204, an AlGaN n-type material layer 206, an AlGaN (or AlInGaN) active region 208, and an AlGaN p-type material layer 210. It will be apparent to one skilled in the art that alternative materials may be substituted for those disclosed here to comprise the various layers. Thus, the scope of the present invention is not be limited to the particular materials used in this disclosed embodiment here.

The semiconductor layers in FIG. 2 are epitaxially grown on substrate 202 (for which transparent sapphire is the most common choice). An n-contact 212 and a p-contact 214 form the electrical connections to the n-type AlGaN layer 206 and p-type AlGaN layer 210, respectively. As will be recognizable to one skilled in the art, contacts 212 and 214 may thus be used to create voltage across the LED for injecting electrons and holes into active region 208. Active region 208 is where the UV or DUV light generation takes place.

This LED device with epilayers facing down is flip-chip bonded onto a high thermal conductive submount 216. This is done using an n-bump 218 and a p-bump 220. N-bump 218 is electrically connected by way of a conductive circuit 222 on top of submount 216. Conductive circuit 222 is then electrically connected to the packing house (not shown) by way of a wire bond 224. Similarly, p-bump 220 is electrically connected to a conductive circuit 226. Circuit 226 is then electrically connected to the packing house (not shown) using a wire bond 224. This completes the electrical circuitry required.

Besides powering the LED, this submount arrangement also provides heat relief. The heat generated in LED active region 208, which is close to epilayer 204, can quickly transfer through metal (or solder) bumps 218 and 220 into the highly-thermally-conductive submount 216. Submount 216 is thermally conductive. It is constructed of a semiconductor material such as ceramic AlN, BN, or Si, SiC. Bumps 218 and 220 are also thermally conductive. In one embodiment they are formed by soldering Pb/Sn, Au/Sn, or other alloys. They may also be formed using metals such as gold (Au) and indium (In).

From there, heat escapes either directly into the environment, or into a package heat sink (metal slug) 230. Heat sink 230 is secured to submount 216 by a solder or thermal paste 232. Heat received into slug 230 is also ultimately exhausted into the environment.

This heat-escape route is made necessary because the sapphire substrate has a very low thermal conductivity. The flip-chip boding, therefore, provides a lower thermal resistance path through the arrangement described in the above paragraph. This ensures that the UV/DUV LED can safely work under a higher current to achieve a higher optical output power.

The light is extracted through the transparent AlN layer 204 and substrate 202. This avoids any light absorption or blockage which might otherwise be caused by p-type semiconductor layer 210, current spreading layers, n- and p-contacts 212 and 214, and bonding wires 224.

The device is encapsulated using an encapsulation material 234 with a hemisphere lens 238 (e.g. sapphire, silica, calcium fluoride) disposed thereon. Lens 238 is cemented on the substrate using a very thin layer 236 of transparent polymer (e.g. PMMA, Teflon™ AF, and Cytop™).

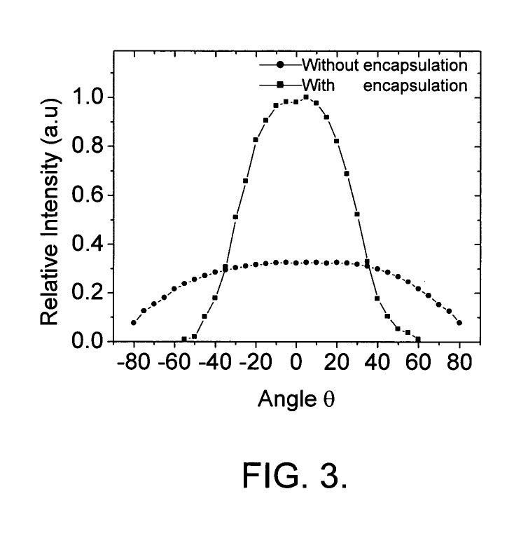

As one example, an AlGaN-based 285 nm DUV LED grown on sapphire substrate was flip-chip bonded on an AlN ceramic submount and then encapsulated. The encapsulation is formed by a truncated crystal sapphire sphere (2 mm in diameter and 1.1 mm in height), which is cemented on the DUV-LED substrate by PMMA. The used PMMA has a molecular weight 950,000 and is formulated in chlorobenzene solvent. PMMA solution is dispensed by dip or spin-coating to form a thin film on the DUV-LED substrate, and then the truncated sapphire sphere is attached to the flip-chip bonded DUV-LED assembly with the LED die in the center and a very thin layer PMMA sandwiched between the substrate and the sapphire lens. After thermal or room-temperature baking to evaporate the solvent, sapphire lens is cemented on the UV-LED. The angular light intensity emitted from the DUV-LED with and without the encapsulation was measured. The measured angular light intensity emitted from 285 nm DUV-LEDs with and without the encapsulation is plotted in FIG. 3. As can be seen, in the forward direction, the total light intensity has been enhanced by a factor of 2-3, demonstrating the enhancement of the light extraction by the encapsulation. More importantly, with the encapsulation, the emitted light has a narrower angular distribution (±50°) instead of (±90°), which is critical for applications requiring high UV/DUV light intensity and focusing. In fact, by varying the size and shape of the encapsulation lens, the angular spread of the emission can be further reduced and controlled.

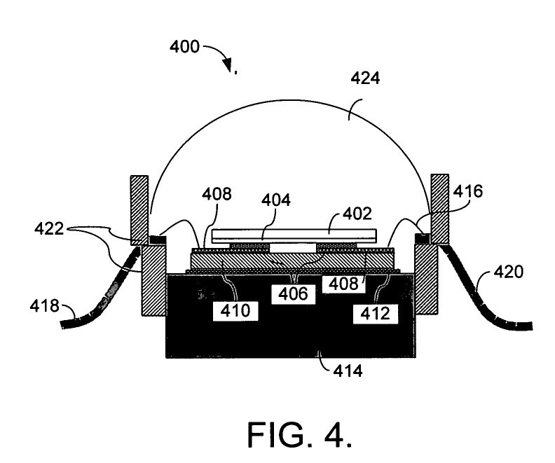

Another embodiment including encapsulation and packaging is shown in FIG. 4. The cross sectional view in the figure shows a flip-chip bonded device 400. Device 400 comprises a UV/DUV die 404 including a sapphire substrate 402. The die 404 is flip-chip mounted in a customized package with enhanced thermal dissipation. This dissipation occurs through a bottom metal slug 414, which may be comprised of Al, Cu, or other thermal conductive materials known to those skilled in the art. The flip-chip mounted UV/DUV LED die is bonded onto a thermally conductive submount 410. Submount 410 may be comprised of ceramic AIN, BN, or Si, SiC materials. The submount assembly is mounted on the metal slug by a layer of thermally-conductive paste 412 (e.g. silver epoxy), or solder such as Au/Sn eutectic alloy.

Through flip-chip and wire bonding (a wire pair 416 is shown in FIG. 4), a set of p- and n-contacts 406 of LED 400 are connected to a first electrical lead 418 and a second electrical lead 420 of the packaging house by a pair of conductive layers 408 which are disposed between the contacts 406 and the submount 410. The packaging house comprises an electrically insulated sidewall 422. Sidewall 422 has a dual tiered taper when viewed in cross section (as shown in FIG. 4). This taper causes it to open outwards toward the top opening, and its inside is coated with a UV reflective layer such as Al film, so the house can be used as a reflection cup. This causes the downwardly and laterally emitted light to be collected and redirected towards the upward opening.

The upward opening is filled by an encapsulation 424. This dome-shaped encapsulation 424 seals the device from the ambient environment and enhances the light extraction. The encapsulation may be formed in the same way as in FIG. 2—by cementing on a lens. Encapsulation dome 424 may alternatively be directly formed in the package house cavity with polymer resins.

Numerous polymer resins may be used. Some examples of materials which are acceptable for use are PMMA solutions, Cytop™ or Teflon™ AF resins, or other UV/DUV transparent fluorinated polymers and siloxanes. PMMA has been used in the preferred embodiment. Other numerous materials could be used as well, so long as they are transaparent in the UV/DUV wavelength ranges. Thus, the above list is not to be considered complete. Other equivalent materials could be used as well to comprise the mold compound to form dome-shape encapsulation 424. The scope of the invention should thus, not be limited to any particular material or group of materials listed herein, because numerous other materials exist which might have sufficient properties.

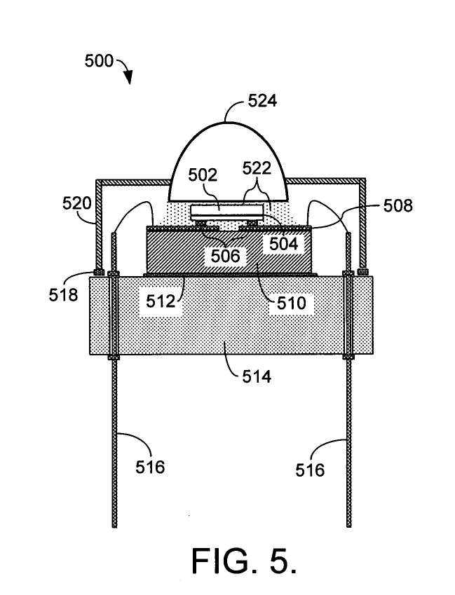

Another embodiment is shown in FIG. 5 with a standard transistor outline TO-style package including a UV/DUV LED 500. TO-style mounts are widely used in the optoelectronics industry. Depending on the size of the submount assembly and the UV/DUV LED thermal dissipation requirements, a different TO-header arrangement may be selected for a particular application, e.g., models TO-3, TO-8, TO-66, TO-220, et al. The FIG. 5 UV/DUV LED submount assembly is bonded on the base plate with solder, silver paste or other die attachment methods, and then the electrical connections are wire bonded to the electrical leads of the package.

This TO type flip-chip mounted LED 500 comprises a UV/DUV die 504 including a substrate 502. A contact pair 506 are used to deliver the necessary voltages. The arrangement has conductive layers 508, on a submount 510 which is connected by a solder/paste adhesion 512 to a header 514. Submount 510 is comprised of ceramic AlN, BN, Si, SiC, or some other thermally advantageous semiconductor material. The electrical system is completed by wire bonding to a pair of leads 516.

A UV/DUV lens 524 made from sapphire, silica or other materials are colleted and sealed at the center opening of a protective metal can 520. The base of the lens is then cemented on the UV/DUV LED by PMMA or some other UV/DUV transparent fluorinated polymer resin encapsulation. At the same time, metal can 520 is fixed to the TO base plate and sealed with an adhesive 518.

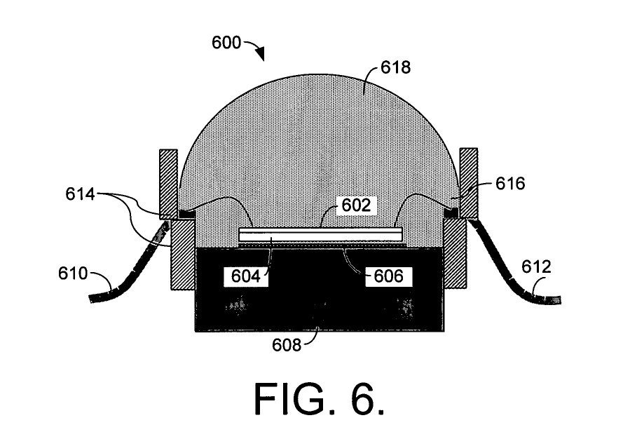

The encapsulation and packaging techniques of the present invention also are adaptable for UV/DUV LEDs packaging without flip-chip bonding. Direct bonding is also possible. Such an embodiment is shown in FIG. 6. The FIG. 6 embodiment is similar to the flip-chip bonded packaging in FIG. 4, except that it is a direct-LED-die attachment embodiment 600. The figure shows a UV/DUV LED 602 with epi-layers facing up. The LED is mounted on a substrate 604. Substrate 604 is directly bonded on a metal slug 608 of the packaging house with a solder or thermal paste 606, and an n- and p-contact pair is wire-bonded (via a wire pair 616) to an electrical lead pair (610 and 612) of the package. An encapsulation dome 618 is directly formed in the package house cavity with polymer resins, just like with the FIG. 4 embodiment. Also like the FIG. 4 embodiment, a dual-tiered side wall arrangement 614 is employed.

The same materials suggested for the FIG. 4 embodiment may be used for the FIG. 6 embodiment as well. It should be understood, however, that other encapsulation materials could be used as well.

For all the disclosed embodiments, it should be understood that though, e.g., AlGaN and AlInGaN based UV/DUV LEDs have been used in the examples in the description, the invention is suitable for the encapsulation and packaging of UV/DUV LEDs based on other UV/DUV materials that can provide UV/DUV emission. Therefore, the invention should not be limited to any particular LED type.

It should also be apparent to those skilled in the art that the same encapsulations shown in FIGS. 2 and 4-6 could also be employed in such a manner that the individual LED disclosed is incorporated into an array of LEDs. The LEDs in such an array would be encapsulated in the same methods disclosed.

The invention has been described with reference to the preferred embodiments. The encapsulation and package layout is only for description purpose. It is to be understood that while certain forms of this invention have been illustrated and described, it is not limited thereto, except in so far as such limitations are included in the following claims and allowable equivalents thereof.

I claim:

1. A device comprising:
a light emitting diode (LED) with a wavelength-emission range from about 360 to about 200 nm;
a substrate onto which said LED is mounted; and
at least part of one of said LED being encapsulated in a protective material, said material being substantially transparent to one of ultraviolet (UV) and deep ultraviolet (DUV) light.

2. The device of claim 1 wherein said material is at least partially organic.

3. The device of claim 1 wherein said material is at least partially inorganic.

4. The device of claim 1 in which said LED is included in an array of LEDs, said array also being encapsulated in said material.

5. The device of claim 1 wherein said LED and substrate are flip-chip bonded onto a submount and disposed in a package house.

6. The device of claim 1 wherein said LED and substrate are directly bonded onto a submount.

7. The device of claim 1 wherein said material is Polymethyl Methacrylate (PMMA).

8. The device of claim 1 wherein said material comprises a fluorinated polymer (fluoropolymer) with optical transparency in the range between about 360 nm to about 200 nm.

9. The device of claim 1 wherein said material comprises one of: (i) a side-chain-fluorinated polymer based on alicyclic and aromatic structures, (ii) a main-chain-fluorinated base resin containing tetrafluoroethylene (TFE), (iii) a monocyclic fluorocarbon, (iv) a siloxane polymer, and (v) sapphire.

10. The device of claim 1 wherein said encapsulation material is constructed into an optically-active form.

11. The device of claim 10 wherein said optically-active form is approximately hemispherical.

12. The device of claim 1 wherein said material comprises one of a fused silica and a silica sol-gel formed in different solvents.

13. The device of claim 1 wherein said device includes a submount which comprises a substance which is thermally conductive.

14. A method encapsulating a light-emitting diode (LED), said LED having a wavelength-emission range from about 360 to about 200 nm, said method comprising:
mounting the LED onto a substrate, and
enclosing said LED in a protective material, said material being substantially transparent to one of ultraviolet (UV) and deep ultraviolet (DUV) light.

15. The method of claim 14 comprising:
flip-chip bonding said LED onto bumps on a submount.

16. The method of claim 15 comprising:
constructing said bumps of a heat-conducting metal.

17. The method of claim 14 comprising:
forming a lens of out of one said material or a second material which is substantially transparent to one of ultraviolet (UV) and deep ultraviolet (DUV) light; and
disposing said lens proximate said LED.

18. The method of claim 17 wherein said forming step further comprises:
performing said lens; and
adhering said lens on said protective material.
